(19) United States
(12) Patent Application Publication
(10) Pub. No.: US 2026/0083002 A1
(43) Pub. Date: Mar. 19, 2026

(54) SEMICONDUCTOR PACKAGE

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/086,301

(22) Filed: Mar. 21, 2025

(30) Foreign Application Priority Data
Sep. 19, 2024 (KR) 10-2024-0126717

(51) Int. Cl. H01L 25/16; G02B 6/42; H01L 21/48; H01L 23/00; H01L 23/053; H01L 23/13; H01L 23/498; H01L 23/538; H10B 80/00; H10D 80/30

(52) U.S. Cl. CPC H10W 90/00; G02B 6/4212; H10W 70/611; H10W 70/65; H10W 70/68; H10W 76/15; H10W 90/401; H10B 80/00; H10D 80/30; H10W 70/05; H10W 72/352; H10W 72/353; H10W 80/312; H10W 80/327; H10W 90/724; H10W 90/734; H10W 90/794

(57) ABSTRACT

A semiconductor package may include a package substrate, an interposer on the package substrate, photonics modules in the interposer and configured to perform communication based on optical signals, and a semiconductor chip on the interposer. A core substrate of the interposer may include through electrodes and cavities, where the through electrodes may extend from an upper surface of the core substrate to a lower surface of the core substrate. The cavities may extend from the upper surface of the core substrate to an inner portion of the core substrate where the through electrodes are not disposed. One of the photonics modules may be in each of the cavities. Each photonics module may include a photonics integrated circuit chip, and an electronic integrated circuit chip and an optical transmissive layer on an upper surface of the photonics integrated circuit chip.

### CROSS-REFERENCE TO RELATED APPLICATION

This application is based on and claims priority under 35 U.S.C. § 119 to Korean Patent Application No. 10-2024-0126717, filed on Sep. 19, 2024, in the Korean Intellectual Property Office, the disclosure of which is incorporated by reference herein in its entirety.

### BACKGROUND

Inventive concepts relate to a semiconductor package, and more particularly, to a semiconductor package which may include a photonics integrated circuit chip and/or an electronic integrated circuit chip.

Semiconductor packages are increasingly being used to enhance functions of electronic devices and/or integrate elements. In semiconductor packages, various integrated circuits, such as a memory chip and a logic chip, may be equipped in a package substrate. Recently, in an environment where data traffic is increasing in data centers and communication infrastructure, research on semiconductor packages including a photonics integrated circuit is ongoing.

### SUMMARY

Inventive concepts provide a semiconductor package which may be high in degree of integration.

Inventive concepts provide a semiconductor package in which a signal distance between a photonics integrated circuit chip and a logic chip may be short.

Aspects of inventive concepts are not limited to the aforesaid, but other aspects not described herein will be clearly understood by those of ordinary skill in the art from descriptions below.

A semiconductor package according to an embodiment may include a package substrate; an interposer on the package substrate; a plurality of photonics modules in the interposer and configured to perform communication based on an optical signal; and a semiconductor chip on the interposer. The interposer may include a core substrate. The core substrate may include a plurality of through electrodes and a plurality of cavities. The plurality of through electrodes may extend from an upper surface of the core substrate to a lower surface of the core substrate. The plurality of cavities may extend from the upper surface of the core substrate to an inner portion of the core substrate. The plurality of cavities may be in a region of the interposer where the plurality of through electrodes are not disposed. A corresponding one of the plurality of photonics modules may be in each of the plurality of cavities. The plurality of photonics modules each may include a photonics integrated circuit chip, an electronic integrated circuit chip on an upper surface of the photonics integrated circuit chip, and an optical transmissive layer on the upper surface of the photonics integrated circuit chip.

A semiconductor package according to an embodiment may include an interposer; a plurality of photonics modules in the interposer and configured to perform communication based on optical signals; a first semiconductor chip on a center of an upper portion of the interposer; and a second semiconductor chip laterally spaced apart from the first semiconductor chip, the second semiconductor chip on the upper portion of the interposer. The interposer may include a core substrate. The core substrate may include a plurality of through electrodes and a plurality of cavities. The plurality of through electrodes may extend from an upper surface of the core substrate to a lower surface of the core substrate. The plurality of cavities may extend from the upper surface of the core substrate to an inner portion of the core substrate and the plurality of cavities may be in a region of the interposer where the plurality of through electrodes are not disposed. A corresponding one of the plurality of photonics modules may be in each of the plurality of cavities. The plurality of photonics modules each may include a photonics integrated circuit chip, an electronic integrated circuit chip on an upper surface of the photonics integrated circuit chip, and an optical transmissive layer on the upper surface of the photonics integrated circuit chip.

A semiconductor package according to an embodiment may include a package substrate; an interposer on the package substrate; a plurality of photonics modules in the interposer and configured to perform communication based on optical signals; a first semiconductor chip on a center of an upper portion of the interposer; a second semiconductor chip laterally spaced apart from the first semiconductor chip and on the upper portion of the interposer; and a lid on the package substrate, the lid covering the interposer, the first semiconductor chip, and the second semiconductor chip. The lid may include an optical fiber facing the interposer. The interposer may include a core substrate. The core substrate may include a plurality of through electrodes and a plurality of cavities. The plurality of through electrodes may extend from an upper surface of the core substrate to a lower surface of the core substrate. The plurality of cavities extend from the upper surface of the core substrate to an inner portion of the core substrate and the plurality of cavities may be in a region of the interposer where the plurality of through electrodes are not disposed. A corresponding one of the plurality of photonics modules may be in each of the plurality of cavities. The plurality of photonics modules each may include a photonics integrated circuit chip, an electronic integrated circuit chip on a first region of an upper surface of the photonics integrated circuit chip, and an optical transmissive layer on a second region of the upper surface of the photonics integrated circuit chip. In one of the plurality of photonics modules in one of the plurality of cavities, the first region of the upper surface of the photonics integrated circuit chip may be closer to the first semiconductor chip compared to the second region of the upper surface of the photonics integrated circuit chip. The second region of the upper surface of the photonics integrated circuit chip may be closer to the second semiconductor chip compared to the first region of the photonics integrated circuit chip. At least a portion of the first region of the photonics integrated circuit chip may overlap the first semiconductor chip in a vertical direction.

### BRIEF DESCRIPTION OF THE DRAWINGS

Embodiments will be more clearly understood from the following detailed description taken in conjunction with the accompanying drawings in which:

FIG. 1 is a perspective view schematically illustrating a semiconductor package according to an embodiment;

FIG. 2 is a plan view schematically illustrating the semiconductor package of FIG. 1;

FIG. 3 is a cross-sectional view of the semiconductor package of FIG. 1 taken along line A1-A1′ of FIG. 2;

FIG. 4 is a perspective view schematically illustrating a photonics module according to an embodiment;

FIG. 5 is a cross-sectional view schematically illustrating a photonics module according to an embodiment;

FIG. 6 is a cross-sectional view schematically illustrating a photonics module according to an embodiment;

FIG. 7 is a plan view for describing a core substrate according to an embodiment;

FIG. 8 is a cross-sectional view for describing a semiconductor package according to an embodiment;

FIGS. 9A and 9B are plan views for describing a configuration of a core substrate according to an embodiment;

FIGS. 10A to 10D are cross-sectional views for describing a configuration of a semiconductor package according to an embodiment; and

FIG. 11 is a flowchart for briefly describing a method of manufacturing a semiconductor package, according to an embodiment.

### DETAILED DESCRIPTION OF THE EMBODIMENTS

Hereinafter, embodiments will be described in detail with reference to the accompanying drawings. Like reference numerals refer to like elements in the drawings, and their repeated descriptions are omitted. When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%). The notion that elements are “substantially the same” may indicate that the element may be completely the same and may also indicate that the elements may be determined to be the same in consideration of errors or deviations occurring during a process.

Herein, a horizontal direction may include a first horizontal direction (an X direction) and a second horizontal direction (a Y direction), which intersect with each other. A direction intersecting with the first horizontal direction (the X direction) and the second horizontal direction (the Y direction) may be referred to as a vertical direction (a Z direction). Herein, a vertical level may be referred to as a height level with respect to a vertical direction (a Z direction) of an arbitrary element.

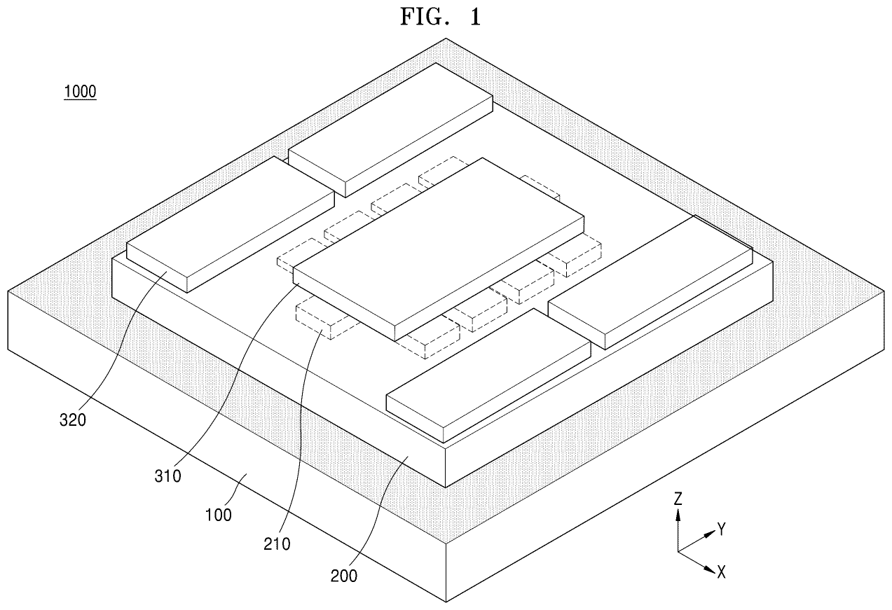

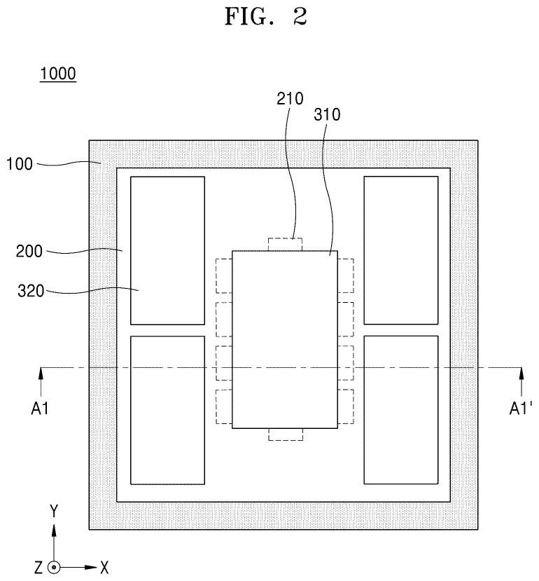

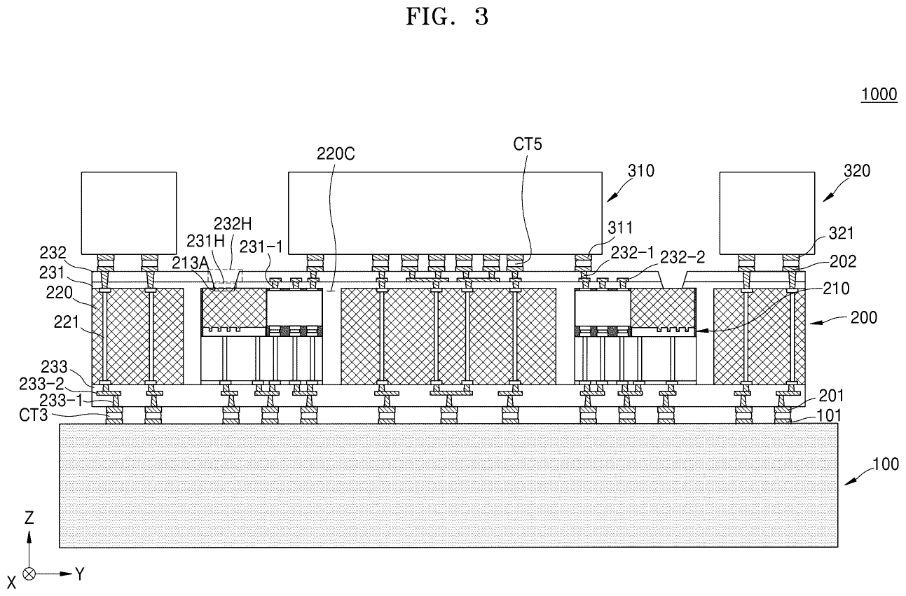

FIG. 1 is a perspective view schematically illustrating a semiconductor package 1000 according to an embodiment. FIG. 2 is a plan view schematically illustrating the semiconductor package 1000 of FIG. 1. FIG. 3 is a cross-sectional view taken along line A-A′ of FIG. 2 in the semiconductor package 1000 of FIG. 1.

Referring to FIGS. 1 and 2, the semiconductor package 1000 may include a package substrate 100, an interposer 200, a photonics module 210, a first semiconductor chip 310, and a second semiconductor chip 320.

The package substrate 100 may be disposed under the interposer 200. The package substrate 100 may be physically and electrically connected to the interposer 200.

The package substrate 100 may be, for example, a printed circuit board (PCB). The package substrate 100 may include an upper pad 101 and a lower pad (not shown). The upper pad 101 and the lower pad (not shown) may each be a portion of a circuit wiring which is patterned after copper (Cu) foil is coated on an upper surface and a lower surface of a substrate included in the package substrate 100. In detail, the upper pad 101 and the lower pad (not shown) may each be a region, which is exposed at the outside without being covered by a solder resist layer, of the circuit wiring.

According to an embodiment, each of the upper pad 101 and the lower pad (not shown) of the package substrate 100 may include copper, nickel, stainless steel, or beryllium copper. An internal wiring electrically connecting the upper pad 101 to the lower pad (not shown) may be provided in the package substrate 100.

Also, the package substrate 100 may include at least one material selected from among phenol resin, epoxy resin, and polyimide. For example, the package substrate 100 may include at least one material selected from among polyimide, frame retardant 4 (FR-4), tetrafunctional epoxy, polyphenylene ether, epoxy/polyphenylene oxide, bismaleimide triazine (BT), THERMOUNT® (a non-woven aramid fiber reinforcement available for Dupont), cyanate ester, and liquid crystal polymer.

The interposer 200 may be disposed on the package substrate 100 and may be disposed under the first semiconductor chip 310 and the second semiconductor chip 320. Also, the interposer 200 may have a cross-sectional area which is less than that of the package substrate 100. The interposer 200 may be disposed between the package substrate 100 and semiconductor chips. The interposer 200 may include a lower pad 201 and an upper pad 202 and may include an internal wiring which electrically connects the lower pad 201 to the upper pad 202.

The interposer 200 may include a core substrate and a plurality of cavities, and a photonics module 210 may be disposed in each of the plurality of cavities. The core substrate and the photonics module 210 accommodated into each of the plurality of cavities will be described below in detail.

The first semiconductor chip 310 and the second semiconductor chip 320 may be disposed on the interposer 200. Here, the first semiconductor chip 310 may be disposed at an upper center of the interposer 200, and the second semiconductor chip 320 may be disposed sideward apart from the first semiconductor chip 310, on the interposer 200.

According to an embodiment, a center axis of the first semiconductor chip 310 and a center axis of the interposer 200 may be substantially equal to each other. Also, as illustrated in FIGS. 1 and 2, the second semiconductor chip 320 may be implemented as four, and each of the four second semiconductor chips 320 may be disposed sideward apart from the first semiconductor chip 310 by the same distance. In this case, each of the four second semiconductor chips 320 may be at a symmetric position with respect to a center point of the first semiconductor chip 310.

However, the arrangement of the first semiconductor chip 310 and the second semiconductor chip 320 illustrated in FIGS. 1 and 2 may be merely an embodiment, and the first semiconductor chip 310 and the second semiconductor chip 320 may be disposed in various forms, based on a size of the interposer 200, a wiring structure, and the number and size of semiconductor chips. For example, one first semiconductor chip 310 may be disposed at a right corner of the interposer 200, and two second semiconductor chips 320 may be disposed in parallel at a left corner of the first semiconductor chip 310, at a position adjacent to the left corner of the first semiconductor chip 310.

Herein, the first semiconductor chip 310 may denote a semiconductor chip which performs functions such as data processing, control, and an arithmetic operation. The first semiconductor chip 310 may be a logic chip. For example, the first semiconductor chip 310 may be an application specific integrated circuit (ASIC). Also, the first semiconductor chip 310 may be implemented as various kinds of semiconductor chips such as a field programmable gate array (FPGA), a graphics processing unit (GPU), a central processing unit (CPU), and a system-on-chip (SoC).

Herein, the second semiconductor chip 320 may denote a semiconductor chip which performs a data storage function. The second semiconductor chip 320 may be a memory chip. For example, the second semiconductor chip 320 may be a dynamic random access memory (RAM) (DRAM) chip. Also, the second semiconductor chip 320 may be implemented as various kinds of semiconductor chips which may each be high bandwidth memory (HBM) where a plurality of DRAM chips are stacked, or may be static RAM (SRAM).

In an embodiment, the first semiconductor chip 310 and the second semiconductor chip 320 may be disposed on the interposer 200 so that an active surface faces the interposer 200. That is, the first semiconductor chip 310 and the second semiconductor chip 320 may be disposed on the interposer 200, based on a face-down type. However, example embodiments are not limited thereto, and the first semiconductor chip 310 and the second semiconductor chip 320 may be disposed on the interposer 200, based on a face-up type.

Referring to FIG. 3, the interposer 200 may include a core substrate 220. The core substrate 220 may include glass. When the core substrate 220 includes glass, a through electrode 221 extending from an upper surface of the core substrate 220 to a lower surface of the core substrate 220 may be a through glass via (TSV). Also, the core substrate 220 may include silicon, and in this case, the through electrode 221 may be a TSV.

The through electrode 221 may be disposed in a two-dimensional (2D) array structure in the core substrate 220. For example, a pitch of the through electrode 221 in the core substrate 220 may be minimized, and thus, signal integrity (SI) may be enhanced.

The through electrode 221 may include metal, conductive metal oxide, or conductive metal nitride. For example, the through electrode 221 may include copper (Cu), tungsten (W), aluminum (Al), nickel (Ni), cobalt (Co), titanium (Ti), or titanium nitride (TiN). In detail, the through electrode 221 may include Cu. The through electrode 221 may be formed through, for example, an electro-plating process. However, example embodiments are not limited thereto, and the through electrode 221 may be formed through another process such as deposition or sputtering.

The core substrate 220 may include a cavity 220C. The cavity 220C may extend into the core substrate 220 from the upper surface of the core substrate 220, in a region where the plurality of through electrodes 221 are not disposed in the core substrate 220.

For example, the cavity 220C may be implemented in a shape which passes through up to the lower surface of the core substrate 220 from the upper surface of the core substrate 220. As another example, the cavity 220C may be implemented in a groove shape where a portion of the core substrate 220 is maintained in a bottom surface without completely passing through up to the lower surface of the core substrate 220 from the upper surface of the core substrate 220.

The photonics module 210 which performs communication based on an optical signal may be disposed in the cavity 220C. FIGS. 1 to 3 are illustrated that a horizontal cross-sectional surface of the cavity 220C has a tetragonal shape, but example embodiments are not limited thereto and the horizontal cross-sectional surface of the cavity 220C may have various shapes such as a circular shape, an oval shape, and a tetragonal shape, based on a shape of the photonics module 210 disposed in the cavity 220C.

The number of cavities 220C included in the core substrate 220 may be implemented in plurality. FIGS. 1 to 3 illustrate ten cavities 220C, but example embodiments are not limited thereto and the number of cavities 220C may be implemented as various numbers, based on a shape and a horizontal cross-sectional area of the core substrate 220 and a position and a cross-sectional area of the first semiconductor chip 310.

The plurality of cavities 220C may be disposed apart from one another by a certain interval in a region adjacent to the first semiconductor chip 310, in the core substrate 220.

According to an embodiment, at least a partial space of the cavity 220C may overlap the first semiconductor chip 310 in a vertical direction. In detail, when a volume of the cavity 220C is “V”, the cavity 220C may be disposed at a position which enables a space of the cavity 220C equal to “0.5*V”to overlap the first semiconductor chip 310 in a vertical direction.

According to an embodiment, at least a partial space of the cavity 220C may not overlap the first semiconductor chip 310 and the second semiconductor chip 320 in a vertical direction. Because the photonics module 210 disposed in the cavity 220C has to receive an optical signal from the outside, at least a partial region of the photonics module 210 may not overlap the first semiconductor chip 310 and the second semiconductor chip 320 in a vertical direction. Therefore, the cavity 220C where the photonics module 210 is disposed may be disposed to include at least a partial space which does not overlap the first semiconductor chip 310 and the second semiconductor chip 320 in a vertical direction. In detail, when a volume of the cavity 220C is “V”, a space having a volume equal to “0.1 V” to may not overlap the first semiconductor chip 310 and the second semiconductor chip 320 in a vertical direction.

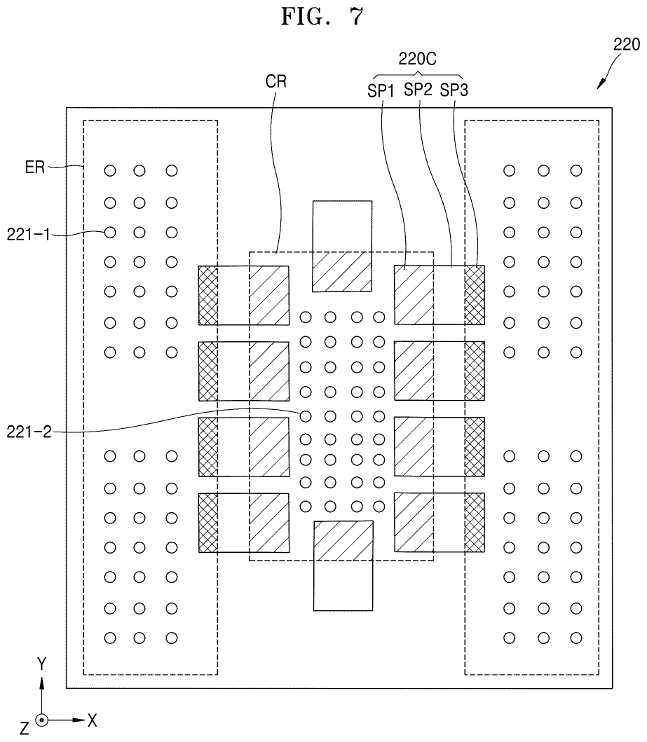

The above description may be merely an embodiment where the cavity 220C is disposed, and the plurality of cavities 220C may be disposed based on various arrangements in the core substrate 220. Various arrangements of the plurality of cavities 220C will be described below in detail with reference to FIG. 7.

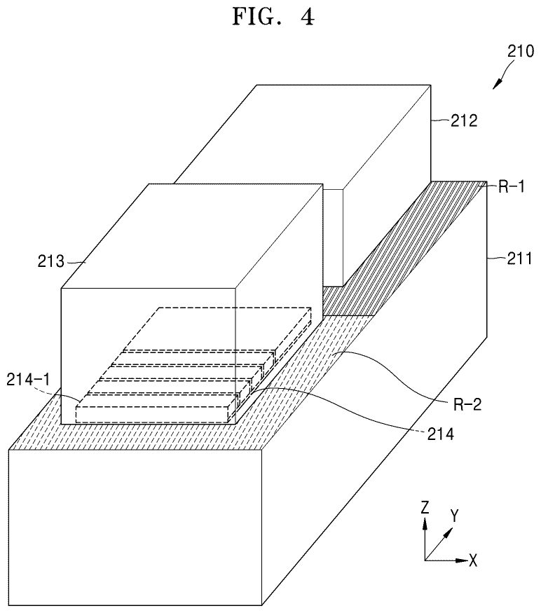

The photonics module 210 may be disposed in the cavity 220C and may include a photonics integrated circuit chip, an electronic integrated circuit chip, and an optical transmissive layer. The photonics module 210 may receive an optical signal through a light incident region 213A and may output an electrical signal to the first semiconductor chip 310. Also, the photonics module 210 may receive an electrical signal from the first semiconductor chip 310 to output an optical signal to the outside of the photonics module 210 through the light incident region 213A. A configuration and a structure of the photonics module 210 will be described below in detail with reference to FIGS. 4 to 6.

The interposer 200 may include an upper redistribution structure and a lower redistribution structure 233. The upper redistribution structure may include a first insulation layer 231 and a second insulation layer 232.

The first insulation layer 231 may cover the upper surface of the core substrate 220 and may cover the other region, except the light incident region 213A, of an upper surface of the photonics module 210. Also, the first insulation layer 231 may fill a space between the core substrate 220 and the photonics module 210, in the cavity 220C. Also, the first insulation layer 231 may include a first redistribution pattern. The first redistribution pattern may include a redistribution via pattern 231-1 and a first redistribution line pattern.

The second insulation layer 232 may cover an upper surface of the first insulation layer 231. The second insulation layer 232 may include a second redistribution pattern. The second redistribution pattern may include a second redistribution via pattern 232-1 and a second redistribution line pattern 232-2.

The first redistribution pattern and the second redistribution pattern may be referred to as an upper redistribution pattern. The upper redistribution pattern may form an electrical connection between the through electrode 221 and the first semiconductor chip 310 and the second semiconductor chip 320 and an electrical connection between the first semiconductor chip 310 and an electric integrated circuit chip included in the photonics module 210. Also, the upper redistribution pattern may form an electrical connection between the first semiconductor chip 310 and the second semiconductor chip 320.

According to an embodiment, the first insulation layer 231 and the second insulation layer 232 may include a photosensitive insulating material. In detail, the first insulation layer 231 and the second insulation layer 232 may include at least one of photosensitive polyimide, polybenzoxazole, phenolic polymer, and benzocyclobutene polymer. Alternatively, the first insulation layer 231 and the second insulation layer 232 may include lead oxide (PbO) including a photosensitizer and polyhydroxystyrene (PHS).

According to an embodiment, the first insulation layer 231 and the second insulation layer 232 may include a non-photosensitive insulating material. When the first insulation layer 231 and the second insulation layer 232 include a non-photosensitive insulating material, the first insulation layer 231 and the second insulation layer 232 may include silicon oxide, silicon nitride, or silicon oxynitride.

According to an embodiment, the first insulation layer 231 and the second insulation layer 232 may include different materials. For example, the first insulation layer 231 may include a material including no filler, and the second insulation layer 232 may include a material including a filler. When the core substrate 220 includes glass, the first insulation layer 231 may include a material including no filler so as to secure a good adhesive force with the core substrate 220. On the other hand, the second insulation layer 232 may include a material including filler and may thus enhance an electrical characteristic and physical stability.

The above description may be merely an embodiment of a material included in each of the first insulation layer 231 and the second insulation layer 232, and the material included in each of the first insulation layer 231 and the second insulation layer 232 is not limited to the embodiment described above.

The first insulation layer 231 may include a first through hole 231H, and the second insulation layer 232 may include a second through hole 232H having the same center axis as that of the first through hole 231H. The first through hole 231H may extend up to a lower surface of the first insulation layer 231 from an upper surface of the first insulation layer 231 and may completely pass through the first insulation layer 231, and the second through hole 232H may extend up to a lower surface of the second insulation layer 232 from an upper surface of the second insulation layer 232 and may completely pass through the second insulation layer 232. As illustrated in FIG. 3, the first through hole 231H and the second through hole 232H may have a shape where a horizontal cross-sectional area progressively increases upward in a vertical direction.

The first through hole 231H and the second through hole 232H may expose the light incident region 213A of the photonics module 210. In detail, the first through hole 231H and the second through hole 232H may be connected to each other. In other words, a horizontal cross-sectional area of an upper surface of the first through hole 231H may be the same as a horizontal cross-sectional area of a lower surface of the second through hole 232H, and the first through hole 231H and the second through hole 232H may overlap the light incident region 213A in a vertical direction. The light incident region 213A may accurately overlap the first through hole 231H and the second through hole 232H in a vertical direction, and thus, the light incident region 213A may receive an optical signal from the outside.

According to an embodiment, the first through hole 231H and the second through hole 232H may be formed through a laser drill process, or may be formed through an etching process.

According to another embodiment, when the first insulation layer 231 and the second insulation layer 232 include a photosensitive material, the first through hole 231H and the second through hole 232H may be formed through a photo process. In detail, an exposure process and a development process may be performed on the first insulation layer 231 and the second insulation layer 232, where the first through hole 231H and the second through hole 232H are not formed. In the exposure process, a mask may be disposed on the second insulation layer 232, and only a portion of each of the first insulation layer 231 and the second insulation layer 232 respectively corresponding to positions of the first through hole 231H and the second through hole 232H may be exposed to light by the mask or may not be exposed.

A process of forming the first through hole 231H and the second through hole 232H described above may be merely an embodiment, and a process of forming a through hole is not limited to the processes.

The lower redistribution structure 233 may include a lower redistribution pattern. The lower redistribution pattern may include a lower redistribution via pattern 233-1 and a lower redistribution line pattern 233-2. The lower redistribution pattern may form an electrical connection between the through electrode 221 and the package substrate 100 and an electrical connection between the photonics integrated circuit chip of the photonics module 210 and the package substrate 100.

An insulation layer of the lower redistribution structure 233 may include the same material as a material included in the first insulation layer 231 or the second insulation layer 232. For example, the insulation layer of the lower redistribution structure 233 may be implemented with a material including a filler as in the second insulation layer 232.

The lower pad 201 of the interposer 200 may be electrically connected to the upper pad 101 of the package substrate 100 through a connection terminal CT3. Here, the connection terminal CT3 may be configured as a connection terminal such as a solder ball or a solder bump.

The upper pad 202 of the interposer 200 may be connected to the lower pad 311 of the first semiconductor chip 310 and the lower pad 321 of the second semiconductor chip 320 through a connection terminal CT5. Here, the connection terminal CT5 may be configured as a connection terminal such as a solder bump or a micro bump.

According to an embodiment, the upper pad 202 of the interposer 200 may be connected to the lower pad 311 of the first semiconductor chip 310 and the lower pad 321 of the second semiconductor chip 320 through a hybrid bonding process. In this case, the semiconductor package 1000 may not include the connection terminal CT5.

Because the semiconductor package 1000 according to an embodiment includes the elements described above, the photonics module 210 including the photonics integrated circuit chip and the electronic integrated circuit chip may be mounted in the interposer 200. Accordingly, the semiconductor package 1000 may convert a received optical signal into an electrical signal and may input the electrical signal to the first semiconductor chip 310 through a minimum path. In describing FIGS. 4 to 6, a configuration of the photonics module 210 which receives an optical signal and converts the received optical signal into an electrical signal will be described below in detail.

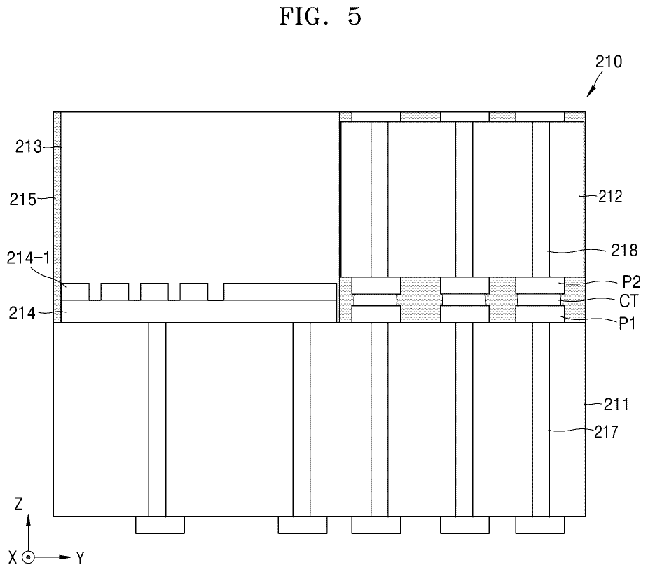

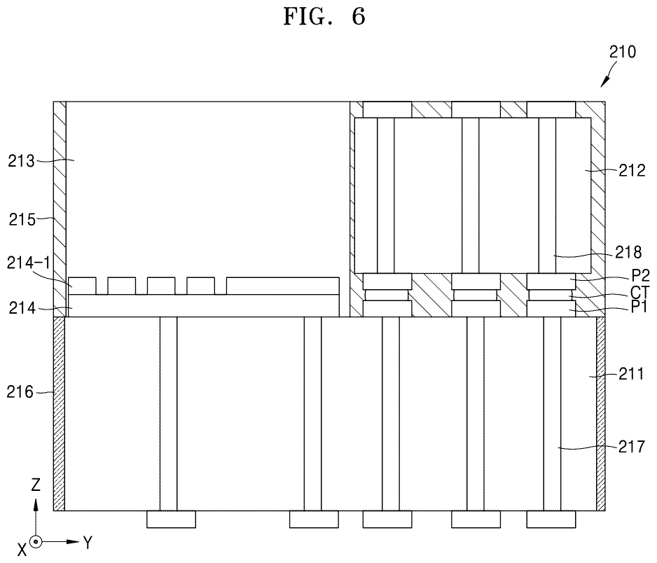

FIG. 4 is a perspective view schematically illustrating a photonics module 210 according to an embodiment. FIG. 5 is a cross-sectional view schematically illustrating a photonics module according to an embodiment. FIG. 6 is a cross-sectional view schematically illustrating a photonics module according to an embodiment.

Referring to FIG. 4, the photonics module 210 may include a photonics integrated circuit chip 211, an electronic integrated circuit chip 212, and an optical transmissive layer 213.

The photonics integrated circuit chip 211 may receive an optical signal and may convert the received optical signal into an electrical signal. The photonics integrated circuit chip 211 may be disposed in the photonics module 210, based on a face-up type. In other words, an active surface of the photonics integrated circuit chip 211 may be disposed toward the electronic integrated circuit chip 212 and the optical transmissive layer 213.

A photoelectric converter may be formed on the active surface of the photonics integrated circuit chip 211. The photoelectric converter of the photonics integrated circuit chip 211 may include a waveguide 214. According to an embodiment, a grid coupler 214-1 may be disposed at one side of the waveguide 214, and a photodiode, a modulator, and an optical detector may be disposed at the other side of the waveguide 214.

The waveguide 214 may be a path through which an optical signal moves in the photonics integrated circuit chip 211. The waveguide 214 may be a path through which an optical signal incident on the grid coupler 214-1 moves to the optical detector, may be a path through which an optical signal converted in the modulator moves to the grid coupler 214-1. For example, an optical signal may move along the waveguide 214 in a horizontal direction in an upper surface of the photonics integrated circuit chip 211.

In a process of inputting an optical signal to the photonics integrated circuit chip 211, the optical detector may detect the optical signal input to the photonics integrated circuit chip 211. The photonics integrated circuit chip 211 may detect an optical signal through the optical detector and may convert the optical signal into an electrical signal. The electrical signal obtained through conversion by the optical detector may be transferred to a plurality of individual elements on the active surface of the photonics integrated circuit chip 211.

The grid coupler 214-1 may be a portion of the waveguide 214. For example, the grid coupler 214-1 may be an element which is in a region, to which an optical signal is input, of an entire region of the waveguide 214. Also, the grid coupler 214-1 may be an element which is in one region, which emits an optical signal through an optical fiber, of the waveguide 214.

According to an embodiment, the grid coupler 214-1 may be a region, where a plurality of grid pins protruding to an upper portion are disposed, of the waveguide 214. For example, the plurality of grid pins may be apart from one another in a vertical direction and may configure a grid structure. The plurality of grid pins may be formed in the upper surface of the photonics integrated circuit chip 211 through an etching process or a deposition process.

The above description may be merely an embodiment of a configuration of the photoelectric converter of the photonics integrated circuit chip 211, and the configuration of the photoelectric converter of the photonics integrated circuit chip 211 is not limited to the elements described above. For example, the photonics integrated circuit chip 211 may further include a laser diode which emits an optical signal, based on a signal received from the modulator.

The upper surface of the photonics integrated circuit chip 211 may be divided into a first region R-1 and a second region R-2. An area of each of the first region R-1 and the second region R-2 may be half of a horizontal cross-sectional area of the upper surface of the photonics integrated circuit chip 211. The first region R-1 may be a region where the electronic integrated circuit chip 212 is disposed. The second region R-2 may be a region where the optical transmissive layer 213 is disposed.

In the cavity 220C, the first region R-1 may be disposed closer to the first semiconductor chip 310 than the second region R-2, and the second region R-2 may be disposed closer to the second semiconductor chip 320 than the first region R-1.

According to an embodiment, at least a portion of the first region R-1 may overlap the first semiconductor chip 310 in a vertical direction. For example, the photonics module 210 may be disposed in the cavity 220C so that a 50% area of a horizontal cross-sectional area of the first region R-1 overlaps the first semiconductor chip 310 in a vertical direction. The first region R-1 may be a region where the electronic integrated circuit chip 212 is disposed, and a path of an electrical signal between the electronic integrated circuit chip 212 and the first semiconductor chip 310 may be reduced as a region overlapping the first semiconductor chip 310 in a vertical direction increases.

According to an embodiment, at least a portion of the second region R-2 may not overlap the first semiconductor chip 310 and the second semiconductor chip 320 in a vertical direction.

For example, the photonics module 210 may be disposed in the cavity 220C so that at least a 10% area of a horizontal cross-sectional area of the second region R-2 does not overlap the first semiconductor chip 310 and the second semiconductor chip 320 in a vertical direction. The second region R-2 may be a region where the optical transmissive layer 213 is disposed, and the light incident region 213A of the optical transmissive layer 213 has to be exposed at the outside of the interposer 200. In this case, when the second region R-2 is disposed at only a position completely overlapping the first semiconductor chip 310 and the second semiconductor chip 320 in a vertical direction, the light incident region 213A may be disposed not to be exposed at the outside. Therefore, the photonics module 210 may be disposed in the cavity 220C so that at least a 10% area of the horizontal cross-sectional area of the second region R-2 does not overlap the first semiconductor chip 310 and the second semiconductor chip 320 in a vertical direction.

The electronic integrated circuit chip 212 may be electrically and physically connected to the photonics integrated circuit chip 211, in the first region R-1. According to an embodiment, the electronic integrated circuit chip 212 may be disposed as a face-down type. That is, the active surface of the electronic integrated circuit chip 212 may be disposed toward the photonics integrated circuit chip 211. However, example embodiments are not limited thereto, and the electronic integrated circuit chip 212 may be disposed in the first region R-1, based on a face-up type.

The electronic integrated circuit chip 212 may include a plurality of individual elements which perform an interface between the photonics integrated circuit chip 211 and the other semiconductor devices. The plurality of individual elements of the electronic integrated circuit chip 212 may be disposed in the active surface of the electronic integrated circuit chip 212. For example, the electronic integrated circuit chip 212 may include a complementary metal oxide semiconductor (CMOS) driver and a trans impedance amplifier, so as to perform a function of controlling high frequency signaling of the photonics integrated circuit chip 211.

The optical transmissive layer 213 may surround the grid coupler 214-1 in the second region R-2 and may transfer an optical signal, input to an upper surface of the optical transmissive layer 213, to the grid coupler 214-1. The optical transmissive layer 213 may include the light incident region 213A. The light incident region 213A may be a region, overlapping the grid coupler 214-1 in a vertical direction, of the upper surface of the optical transmissive layer 213. An optical signal incident through the light incident region 213A may have various wavelengths. For example, an optical signal input to the optical transmissive layer 213 through a single-mode optical fiber (SMF) may have wavelengths of about 1,310 nm, about 1,550 nm, and about 1,625 nm, and an optical signal input to the optical transmissive layer 213 through a multi-mode optical fiber (MMF) may have wavelengths of about 850 nm and about 1,300 nm.

Because the optical transmissive layer 213 has to perform a function of transmitting an optical signal to transfer the optical signal to the grid coupler 214-1, the optical transmissive layer 213 may include a material having a high light transmittance.

According to an embodiment, in a case where an optical signal having a wavelength of about 850 nm is incident on the light incident region 213A, the optical transmissive layer 213 may include at least one material selected from among quartz glass, indium phosphide, gallium arsenide, and ZBLAN glass. Quartz glass, indium phosphide, gallium arsenide, and ZBLAN glass may be about 60% or more in transmittance to an optical signal having a wavelength of about 850 nm, and thus, may be selected as a material of the optical transmissive layer 213.

According to an embodiment, when an optical signal having wavelengths of about 1,300 nm, about 1,310 nm, about 1,550 nm, and about 1,625 nm is incident on the light incident region 213A, the optical transmissive layer 213 may include at least one material selected from among silicon, quartz glass, indium phosphide, gallium arsenide, and ZBLAN glass. Silicon, quartz glass, indium phosphide, gallium arsenide, and ZBLAN glass may be about 60% or more in transmittance to an optical signal having a wavelength of about 850 nm, and thus, may be selected as a material of the optical transmissive layer 213.

The above description may be merely an embodiment of a material included in the optical transmissive layer 213, and the material of the optical transmissive layer 213 is not limited to the embodiment described above.

According to an embodiment, the photonics module 210 illustrated in FIG. 5 may be manufactured based on a chip on wafer (CoW) process.

For detailed example, a manufacturing process of the photonics module 210 may be performed in the following order. First, a wafer including a plurality of photonics integrated circuit chips 211 having a non-diced state may be provided. Also, the electronic integrated circuit chip 212 and the optical transmissive layer 213 may be disposed on an upper surface of each of the plurality of photonics integrated circuit chips 211 included in the wafer through a pick and place method. Also, a molding process of forming a second molding layer 215 surrounding the electronic integrated circuit chip 212 and the optical transmissive layer 213 may be performed. Also, by performing a singulation process on the wafer, a plurality of photonics modules 210 may be obtained.

The above description may merely describe only a main process operation of a CoW process of forming the photonics module 210, and a plurality of detailed processes may be provided between the main processes described above. For example, several detailed processes such as a process of forming a metal pad on the upper surface of the photonics integrated circuit chip 211 and a process of bonding the photonics integrated circuit chip 211 to the electronic integrated circuit chip 212 may be further provided between an operation of providing the wafer and an operation of placing the electronic integrated circuit chip 212 and the optical transmissive layer 213 through the pick and place method.

A process sequence described above may be merely an embodiment, and a method of manufacturing the photonics module 210 based on the CoW process is not limited to the embodiment described above.

Referring to FIG. 5, an upper pad P1 of the photonics integrated circuit chip 211 may be connected to a lower pad P2 of the electronic integrated circuit chip 212 through a connection terminal CT. For example, the connection terminal CT may be configured as a connection terminal such as a micro bump or a solder bump.

According to an embodiment, a connection between the photonics integrated circuit chip 211 and the electronic integrated circuit chip 212 may be formed based on hybrid bonding. In this case, the upper pad P1 of the photonics integrated circuit chip 211 may be connected to the lower pad P2 of the electronic integrated circuit chip 212, and the semiconductor package 1000 may not include the connection terminal CT.

The optical transmissive layer 213, as described above, may be disposed in the second region R-2 of the upper surface of the photonics integrated circuit chip 211 through a pick and place method. In detail, the optical transmissive layer 213 may be adhered to a region, which may surround the grid coupler 214-1, of the second region R-2 through an adhesive or an adhesive film.

The photonics integrated circuit chip 211 may include a through electrode 217 which connects an active surface of the photonics integrated circuit chip 211 to an inactive surface of the photonics integrated circuit chip 211. The through electrode 217 of the photonics integrated circuit chip 212 may be electrically connected to the photoelectric converter including the waveguide 214, the upper pad P1, and the lower pad of the photonics integrated circuit chip 211.

The electronic integrated circuit chip 212 may include a through electrode 218 which connects an active surface of the electronic integrated circuit chip 212 to an inactive surface of the electronic integrated circuit chip 212. The through electrode 218 of the electronic integrated circuit chip 212 may be electrically connected to the lower pad P2 of the electronic integrated circuit chip 212.

The second molding layer 215 may surround an upper surface of the photonics integrated circuit chip 211, a side surface and a lower surface of the electronic integrated circuit chip 212, and a side surface of the optical transmissive layer 213. In a case where the photonics module 210 is manufactured through a CoW process, the electronic integrated circuit chip 212 and the optical transmissive layer 213 may be disposed on the upper surface of the photonics integrated circuit chip 211 of a wafer state, and thus, a molding layer surrounding the photonics integrated circuit chip 211 may not be provided. Here, the second molding layer 215 may include at least one material selected from among phenol resin, epoxy resin, and polyimide. For example, the second molding layer 215 may include an epoxy mold compound (EMC).

According to an embodiment, the photonics module 210 illustrated in FIG. 6 may be manufactured based on a chip on reconstituted wafer (CoRW) process.

For detailed example, a manufacturing process of the photonics module 210 may be performed in the following order. First, a reconstituted wafer which is disposed so that a plurality of photonics integrated circuit chips 211 are apart from one another by a certain interval on a wafer may be provided. Also, a molding process of forming a first molding layer 216 surrounding the plurality of photonics integrated circuit chips 211 may be performed. Also, the electronic integrated circuit chip 212 and the optical transmissive layer 213 may be disposed on an upper surface of each of the plurality of photonics integrated circuit chips 211 through a pick and place method. Also, a molding process of forming the second molding layer 215 surrounding the electronic integrated circuit chip 212 and the optical transmissive layer 213 may be performed. Subsequently, by performing a singulation process on the reconstituted wafer, the plurality of photonics modules 210 may be obtained.

The above description may merely describe only a main process operation of a CoRW process of forming the photonics module 210, and a plurality of detailed processes may be provided between the main processes described above. For example, several detailed processes such as a process of polishing the upper surface of the first molding layer 216 and a process of bonding the photonics integrated circuit chip 211 to the electronic integrated circuit chip 212 may be further provided between an operation of forming the first molding layer 216 and an operation of placing the electronic integrated circuit chip 212 and the optical transmissive layer 213 through the pick and place method.

A process sequence described above may be merely an embodiment, and a method of manufacturing the photonics module 210 based on the CoRW process is not limited to the embodiment described above.

Comparing with the photonics module illustrated in FIG. 5, the photonics module illustrated in FIG. 6 may further include the first molding layer 216.

The photonics module 210 may include each of the first molding layer 216 surrounding a side surface of the photonics integrated circuit chip 211 and the second molding layer 215 surrounding the optical transmissive layer 213 and a side surface of the electronic integrated circuit chip 212.

According to an embodiment, the photonics integrated circuit chip 211 disposed in a lower layer and the electronic integrated circuit chip 212 and the optical transmissive layer 213 each disposed in a relatively upper layer may differ in coefficient of thermal expansion. In this case, the first molding layer 216 and the second molding layer 215 may include different materials.

For example, when a coefficient of thermal expansion of the photonics integrated circuit chip 211 is relatively higher than a coefficient of thermal expansion of each of the electronic integrated circuit chip 212 and the optical transmissive layer 213, a material included in the first molding layer 216 may be higher in coefficient of thermal expansion than a material included in the second molding layer 215.

As another example, when a coefficient of thermal expansion of the photonics integrated circuit chip 211 is relatively higher than a coefficient of thermal expansion of each of the electronic integrated circuit chip 212 and the optical transmissive layer 213, the material included in the first molding layer 216 may be higher in Young's modulus than the material included in the second molding layer 215.

As in the method described above, because the material of the first molding layer 216 differs from that of the second molding layer 215, a coefficient of thermal expansion of the photonics integrated circuit chip 211, a coefficient of thermal expansion of the electronic integrated circuit chip 212, and a coefficient of thermal expansion of the optical transmissive layer 213 may differ, thereby limiting and/or preventing the occurrence of a warpage phenomenon.

The photonics module 210 according to an embodiment may include the configuration and the structure each described above, and thus, may receive an optical signal from an optical fiber to transfer an electrical signal to the first semiconductor chip 310 through a minimum path. Also, the photonics module 210 described above may be disposed in the cavity 220C formed in the core substrate 220, and thus, a position at which the cavity 220C is disposed in the core substrate 220 will be described below in detail with reference to FIG. 7.

FIG. 7 is a plan view for describing a core substrate 220 according to an embodiment.

The core substrate 220 may include a center region CR and an edge region ER. Here, the center region CR may be a region which is disposed at a center of the core substrate 220 and is in the core substrate 220. In detail, the center region CR may be a region which overlaps the first semiconductor chip 310, disposed at a center of an upper portion of the interposer 200, in a vertical direction.

According to an embodiment, a horizontal cross-sectional surface of the center region CR may have a shape corresponding to a bottom surface of the first semiconductor chip 310. For example, when the bottom surface of the first semiconductor chip 310 has a rectangular shape, the center region CR may be implemented in a cuboid including a rectangular bottom surface. In this case, a vertical-direction height of the cuboid may be equal to a height of the core substrate 220.

Also, the edge region ER may be a region which is disposed adjacent to left and right corners of the core substrate 220 and is in the core substrate 220. In detail, the edge region ER may be a region which overlaps the second semiconductor chip 320, disposed at an outer portion of the upper portion of the interposer 200, in a vertical direction.

According to an embodiment, a horizontal cross-sectional surface of the edge region ER may have a shape corresponding to a shape where bottom surfaces of adjacent second semiconductor chips 320 are connected to each other. Returning to FIG. 2, as illustrated in FIG. 2, a case where four second semiconductor chips 320 are disposed at symmetric positions with respect to the first semiconductor chip 310. In this case, the edge region ER may include a horizontal cross-sectional surface corresponding to a shape where two second semiconductor chips 320 adjacent to each other are connected to each other and may include a horizontal cross-sectional surface having a rectangular shape where a vertical length is longer than a horizontal length. In this case, a vertical-direction height of the edge region ER may be equal to a height of the core substrate 220.

The cavity 220C may be a space which extends from the upper surface of the core substrate 220 to an inner portion of the core substrate 220, in a region where a first through electrode 221-1 disposed in the edge region ER and a second through electrode 221-2 disposed in the center region CR are not provided.

According to an embodiment, a plurality of cavities 220C may be arranged at a certain interval in a horizontal direction along a side surface of the center region CR. In this case, each of the plurality of cavities 220C may include a first space SP1, a second space SP2, and a third space SP3.

Here, the first space SP1 may be a space, included in the center region CR, of a space included in the cavity 220C. The second space SP2 may be a space, which is not included in the center region CR and the edge region ER, of the space included in the cavity 220C. The third space SP3 may be a space, included in the edge region ER, of the space included in the cavity 220C.

For example, the second space SP2 may be at least 10% or more space of an entire space included in the cavity 220C. The photonics module 210 may be disposed in the cavity 220C and may receive an optical signal from the outside. Here, the optical signal may be input toward the second space SP2 from an upper portion of the interposer 200. Therefore, the second space SP2 may occupy at least 10% or more space of the entire space included in the cavity 220C, so that an optical signal is stably input to the photonics module 210.

As described above, because each of the plurality of cavities 220C includes the first space SP1 and the third space SP3, an entire space of the interposer 200 may be efficiently used. In detail, in the semiconductor package 1000 according to an embodiment, the photonics module 210 may be disposed in the cavity 220C overlapping at least a portion of the first semiconductor chip 310 and at least a portion of the second semiconductor chip 320 in a vertical direction, and thus, the semiconductor package 1000 may include a number of signal lines without enlarging a horizontal cross-sectional area of the interposer 200.

Also, because the cavity 220C includes the first space SP1, a connection path between the photonics module 210 and the first semiconductor chip 310 may be formed in a vertical direction and may thus be shortened. Accordingly, the semiconductor package 1000 may secure high signal integrity.

The number of first through electrodes 221-1, second through electrodes 221-2, and cavities 220C illustrated in FIG. 7 may be merely for convenience of description, and the number of first through electrodes 221-1, second through electrodes 221-2, and cavities 220C included in the core substrate 220 may be more than the illustration of FIG. 7.

FIG. 7 illustrates a case where the plurality of cavities 220C include only the third space SP3, but as illustrated in FIGS. 1 to 3, the plurality of cavities 220C may include only the first space SP1 and the second space SP2 and may not include the third space SP3. In other words, the plurality of cavities 220C may not overlap the second semiconductor chip 320 in a vertical direction.

Also, in the drawings, all of the plurality of cavities 220C are illustrated as including the first space SP1, but the plurality of cavities 220C may not include the first space SP1 and the third space SP3. In other words, the plurality of cavities 220C may be disposed in a region which does not overlap the first semiconductor chip 310 and the second semiconductor chip 320 in a vertical direction. Even when the cavity 220C does not include the first space SP1, because the photonics integrated circuit chip 211 and the electronic integrated circuit chip 212 are disposed in the interposer 200, the semiconductor package 1000 may include a signal path which is shorter than that of a conventional photonics semiconductor package. Accordingly, the semiconductor package 1000 may secure high signal integrity.

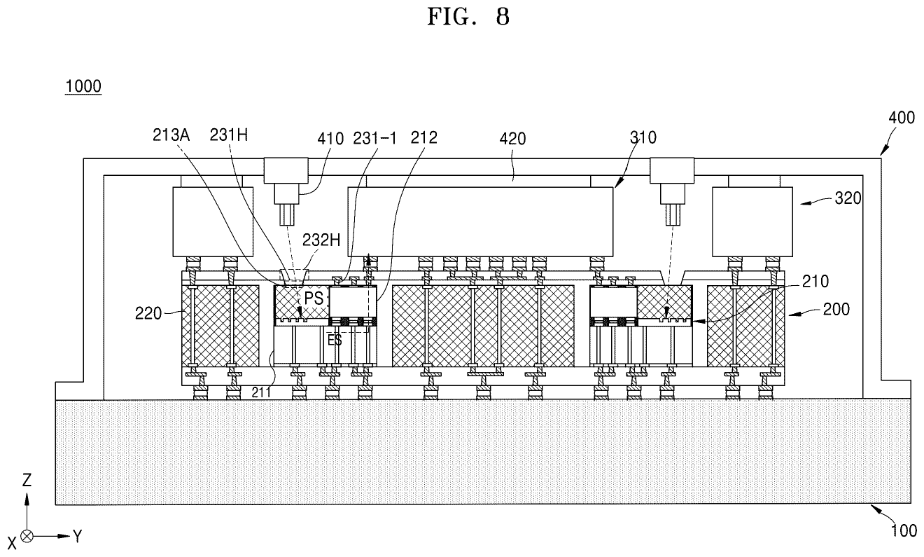

FIG. 8 is a cross-sectional view for describing a semiconductor package 1000 according to an embodiment.

Referring to FIG. 8, the semiconductor package 1000 according to an embodiment may include a lid 400 and an optical fiber 410.

The lid 400 may be disposed on a package substrate 100 and may cover a first semiconductor chip 310, a second semiconductor chip 320, and an interposer 200. In detail, the lid 400 may perform a function of isolating the first semiconductor chip 310, the second semiconductor chip 320, and the interposer 200 from the outside.

The lid 400 may protect the first semiconductor chip 310, the second semiconductor chip 320, and the interposer 200 from dust, water, and an impact. Also, the lid 400 may be connected to the first semiconductor chip 310 and the second semiconductor chip 320 through a connection member 420. The connection member 420 may transfer heat, occurring in the first semiconductor chip 310 and the second semiconductor chip 320, to the lid 400. For example, the connection member 420 may include a material, having good thermal conductivity, such as thermal conductive ceramic and aluminum.

The optical fiber 410 may be coupled to a position facing an optical transmissive layer 213, in an upper surface of the lid 400. According to an embodiment, the optical fiber 410 may be disposed at a position overlapping a light incident region 213A of the optical transmissive layer 213 in a vertical direction. Also, the optical fiber 410 may be disposed at a position overlapping a first through hole 231H and a second through hole 232H in a vertical direction.

The optical fiber 410 may emit an optical signal PS to the light incident region 213A. The optical signal PS emitted from the optical fiber 410 may pass through the optical transmissive layer 213 and may reach a grid coupler 214-1. The optical signal PS reaching the grid coupler 214-1 may move along a waveguide 214, and an optical detector may detect the optical signal PS moving along the waveguide 214 and may convert the optical signal PS into an electrical signal ES. Here, the optical signal PS which has moved toward the grid coupler 214-1 from the optical fiber 410 may be incident with an incident angle of about 45 degrees to about 90 degrees with respect to the optical transmissive layer 213.

The electrical signal ES obtained through conversion by the optical detector may move from a photonics integrated circuit chip 211 to an electronic integrated circuit chip 212. Also, the electrical signal ES may move from the electronic integrated circuit chip 212 to the first semiconductor chip 310. Here, a signal line through which the electrical signal ES moves from the electronic integrated circuit chip 212 to the first semiconductor chip 310 may form a vertical-direction path.

As described above, a path of a signal moving toward the electronic integrated circuit chip 212 from the photonics integrated circuit chip 211 and a path of a signal moving toward the first semiconductor chip 310 from the electronic integrated circuit chip 212 may each be formed as a vertical path. As a result, the semiconductor package 1000 according to an embodiment may secure high signal integrity.

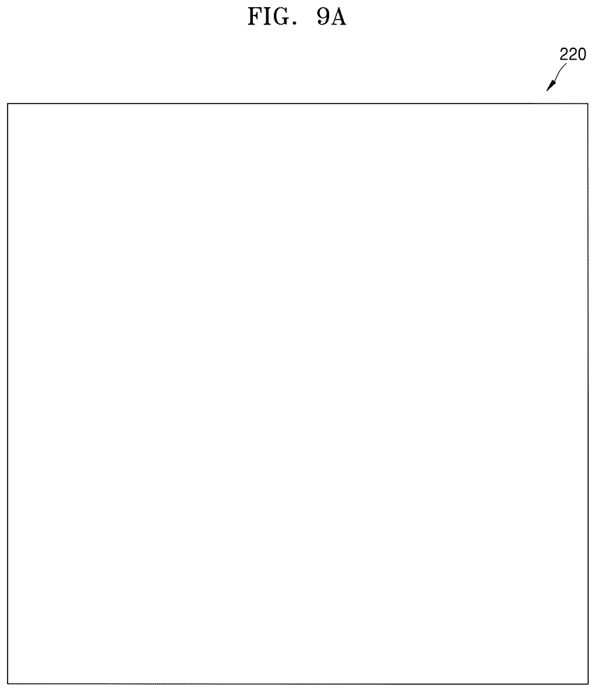

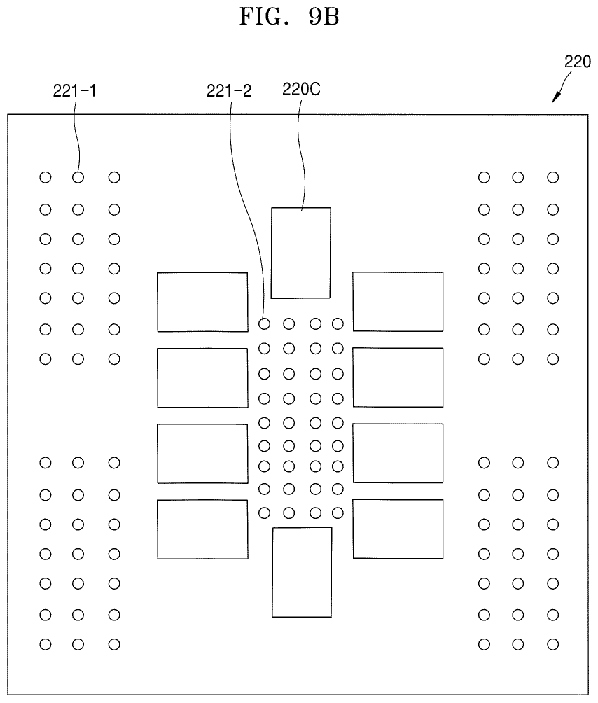

FIGS. 9A and 9B are plan views for describing a configuration of a core substrate 220 according to an embodiment.

Referring to FIG. 9A, the core substrate 220 may include a horizontal cross-sectional surface having a tetragonal shape.

Referring to FIG. 9B, the core substrate 220 may include a first through electrode 221-1, a second through electrode 221-2, and a plurality of cavities 220C. The core substrate 220 illustrated in FIG. 9B may be manufactured by performing a process of forming the first through electrode 221-1, the second through electrode 221-2, and the plurality of cavities 220C in the core substrate 220 illustrated in FIG. 9A.

According to an embodiment, the process of forming the first through electrode 221-1, the second through electrode 221-2, and the plurality of cavities 220C in the core substrate 220 may be a laser induced deep etching (LIDE) process. In detail, a laser may be exposed at positions at which the first through electrode 221-1, the second through electrode 221-2, and the plurality of cavities 220C are to be formed. A certain region, exposed to the laser, of the core substrate 220 may be strained to a state where etching is chemically easy. Subsequently, the core substrate 220 may be dipped in an etching solution. When the core substrate 220 contacts the etching solution, a region exposed to a laser may be selectively etched. Accordingly, only a region where the first through electrode 221-1, the second through electrode 221-2, and the plurality of cavities 220C are to be formed may be selectively etched in an entire region of the core substrate 220.

The LIDE process described above may be merely an example of several processes of forming the first through electrode 221-1, the second through electrode 221-2, and the plurality of cavities 220C in the core substrate 220, and the process is not limited to the LIDE process.

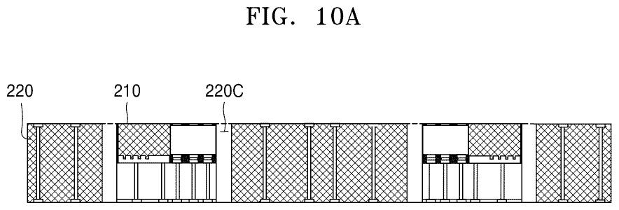

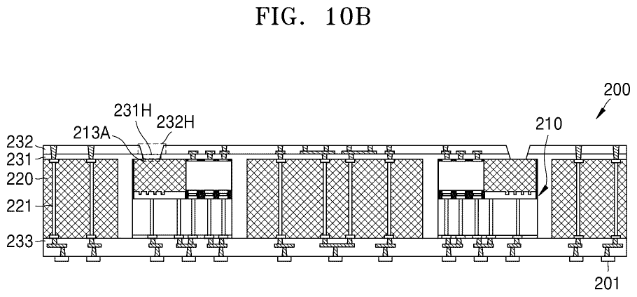

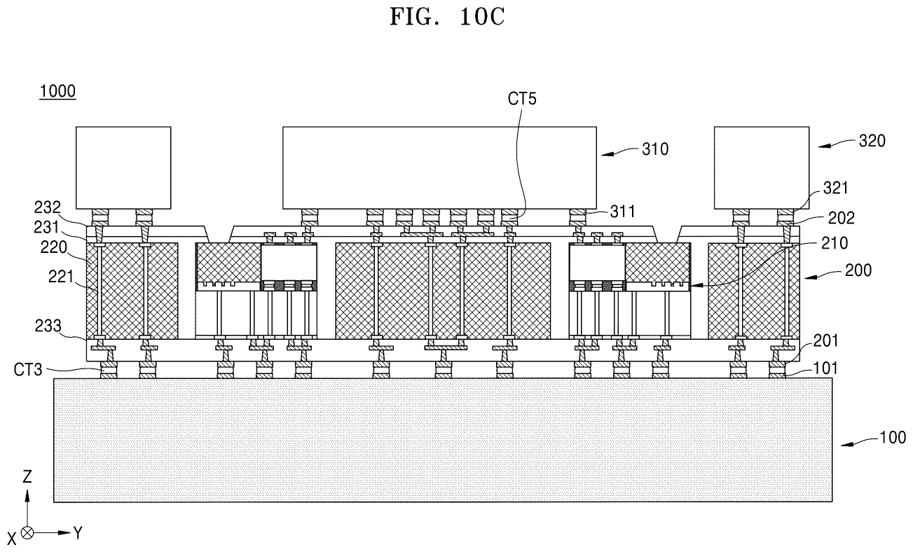

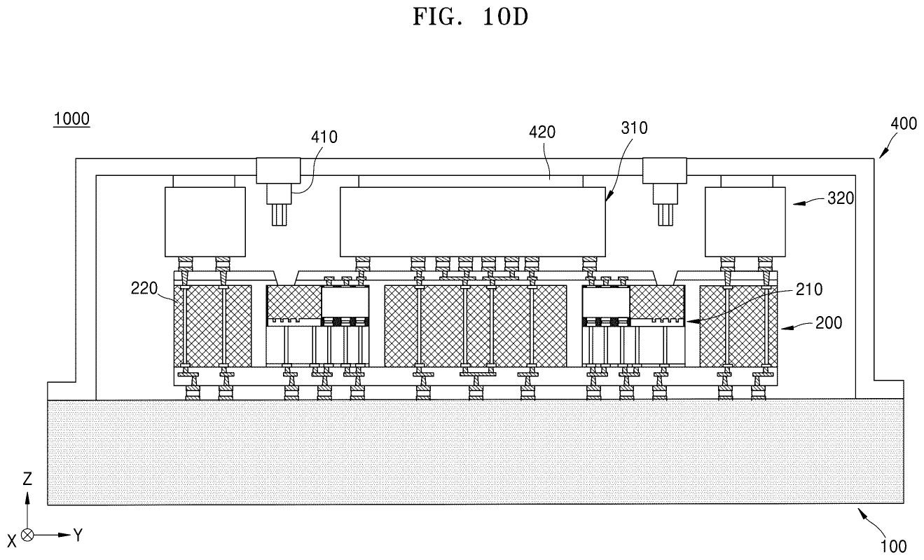

FIGS. 10A to 10D are cross-sectional views for describing a configuration of a semiconductor package 1000 according to an embodiment.

Referring to FIG. 10A, a photonics module 210 may be disposed in a core substrate 220 where a plurality of first through electrodes 221-1, a plurality of second through electrodes 221-2, and a plurality of cavities 220C are formed as illustrated in FIG. 9B.

According to an embodiment, the core substrate 220 where the first through electrode 221-1, the second through electrode 221-2, and the plurality of cavities 220C are formed may be disposed on a carrier wafer. Subsequently, the photonics module 210 may be disposed in each of the plurality of cavities 220C of the core substrate 220.

Referring to FIG. 10B, an interposer 200 may include the core substrate 220 and an upper redistribution structure and a lower redistribution structure 233 each surrounding the core substrate 220.

According to an embodiment, the upper redistribution structure surrounding the core substrate 220 where the photonics module 210 is disposed in each of the plurality of cavities 220C may be manufactured. Here, the upper redistribution structure may include a first insulation layer 231 and a second insulation layer 232.

In detail, the first insulation layer 231 surrounding the core substrate 220 may be formed, and an upper redistribution pattern included in the first insulation layer 231 may be formed. Subsequently, the second insulation layer 232 covering an upper surface of the first insulation layer 231 may be formed, and an upper redistribution pattern included in the second insulation layer 232 may be formed.

Subsequently, a process of respectively forming a first through hole 231H and a second through hole 232H in the first insulation layer 231 and the second insulation layer 232 may be performed. Here, the process of forming the first through hole 231H and the second through hole 232H may be performed through a laser drilling process or a photo process. For example, when all of the first insulation layer 231 and the second insulation layer 232 include a photosensitive material, the first through hole 231H and the second through hole 232H may be respectively formed in the first insulation layer 231 and the second insulation layer 232 through a photo process.

Here, the first through hole 231H and the second through hole 232H may be connected to each other and may be implemented in a tapered shape where a horizontal cross-sectional area increases progressively toward an upper side.

Subsequently, the lower redistribution structure 233 surrounding a lower surface of the core substrate 220 may be manufactured. After the lower redistribution structure 233 is manufactured, a lower pad 201 connected to lower redistribution patterns of the lower redistribution structure 233 may be formed.

Referring to FIG. 10C, the semiconductor package 1000 may include a package substrate 100, an interposer 200, a first semiconductor chip 310, and a second semiconductor chip 320.

As illustrated in FIG. 10B, the first semiconductor chip may be disposed at a center of an upper portion of the interposer 200, and the second semiconductor chip 320 may be disposed at a position sideward apart from the first semiconductor chip 310 on the interposer 200. Subsequently, the interposer 200 may be disposed on the package substrate 100.

Referring to FIG. 10D, the semiconductor package 1000 may further include a lid 400, an optical fiber 410, and a connection member 420.

The connection member 420 may be formed on an upper surface of each of the first semiconductor chip 310 and the second semiconductor chip 320 each illustrated in FIG. 10C. The connection member 420 may be attached to the upper surface of each of the first semiconductor chip 310 and the second semiconductor chip 320 through an adhesive film or an adhesive. Subsequently, the lid 400 may be disposed on an upper surface of the package substrate 100 illustrated in FIG. 10C. The lid 400 may be connected to the connection member 420. Subsequently, the optical fiber 410 may be coupled to a position facing an optical transmissive layer 213, in an upper surface of the lid 400.

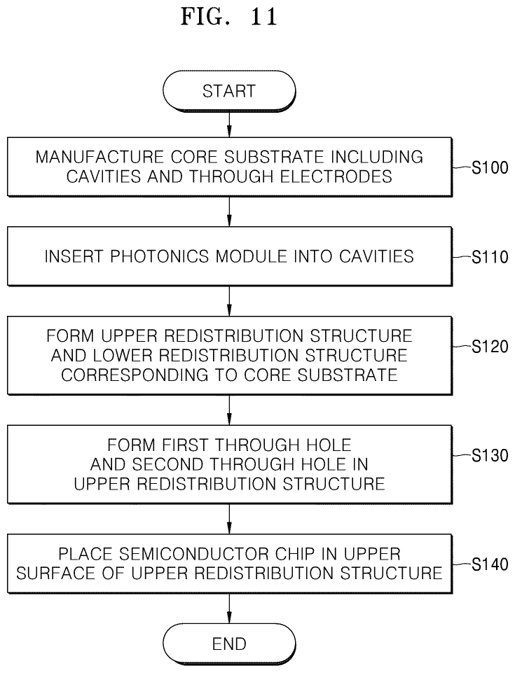

FIG. 11 is a flowchart for briefly describing a method of manufacturing a semiconductor package, according to an embodiment.

In operation S100, a core substrate including a plurality of cavities and a plurality of through electrodes may be manufactured. Here, a process of manufacturing the core substrate including the plurality of cavities and the plurality of through electrodes may be an LIDE process. The descriptions of the process may be the same as the descriptions of FIGS. 9A and 9B.

In operation S110, a photonics module may be inserted into each of the plurality of cavities. Subsequently, in operation S120, an upper redistribution structure and a lower redistribution structure each corresponding to the core substrate may be formed. Subsequently, in operation S130, a first through hole and a second through hole may be formed in the upper redistribution structure. The detailed descriptions of operation S110, operation S120, and operation S130 may be the same as the descriptions of FIGS. 10A to 10D.

Subsequently, in operation S140, a semiconductor chip may be disposed on an upper surface of the upper redistribution structure. For example, a first semiconductor chip may be disposed at a center of the upper surface of the upper redistribution structure, and a plurality of second semiconductor chips may be disposed at positions sideward apart from the first semiconductor chip. Also, the semiconductor chips may be electrically connected to the upper redistribution structure by elements such as a connection terminal and a pad, which are on the upper surface of the upper redistribution structure.

FIG. 11 merely illustrates the method of manufacturing the semiconductor package according to an embodiment, and the method of manufacturing the semiconductor package according to example embodiments are not limited to the embodiments described above.

The photonics module provided in the interposer may be embedded in the semiconductor package according to an embodiment. Accordingly, the semiconductor package may minimize a signal path between a photonics integrated circuit chip and a semiconductor chip.

Hereinabove, example embodiments have been described in the drawings and the specification. Embodiments have been described by using the terms described herein, but this has been merely used for describing inventive concepts and has not been used for limiting a meaning or limiting the scope of inventive concepts defined in the following claims. Therefore, it may be understood by those of ordinary skill in the art that various modifications and other equivalent embodiments may be implemented from inventive concepts. Accordingly, the spirit and scope of inventive concepts may be defined based on the spirit and scope of the following claims.

While inventive concepts has been particularly shown and described with reference to embodiments thereof, it will be understood that various changes in form and details may be made therein without departing from the spirit and scope of the following claims.

What is claimed is:

1. A semiconductor package comprising:
a package substrate;
an interposer on the package substrate;
a plurality of photonics modules in the interposer and configured to perform communication based on an optical signal; and
a semiconductor chip on the interposer,
wherein the interposer includes a core substrate,
the core substrate includes a plurality of through electrodes and a plurality of cavities,
the plurality of through electrodes extend from an upper surface of the core substrate to a lower surface of the core substrate,
the plurality of cavities extend from the upper surface of the core substrate to an inner portion of the core substrate and the plurality of cavities are in a region of the interposer where the plurality of through electrodes are not disposed,
a corresponding one of the plurality of photonics modules is in each of the plurality of cavities, and
the plurality of photonics modules each include a photonics integrated circuit chip, an electronic integrated circuit chip on an upper surface of the photonics integrated circuit chip, and an optical transmissive layer on the upper surface of the photonics integrated circuit chip.

2. The semiconductor package of claim 1, wherein
the plurality of cavities in the interposer are arranged at regular intervals in a horizontal direction along a side surface of a center region of the core substrate,
each of the plurality of cavities comprises a first space in the center region of the core substrate and a second space outside the center region of the core substrate, and
the center region of the core substrate is a region in the core substrate that overlaps the semiconductor chip in a vertical direction.

3. The semiconductor package of claim 1, wherein,
in the plurality of photonics modules,
the electronic integrated circuit chip is on a first region of an upper surface of the photonics integrated circuit chip, and
the optical transmissive layer is on a second region of the upper surface of the photonics integrated circuit chip,
in one of the plurality of cavities, the first region of the upper surface of the photonics integrated circuit chip is closer to the semiconductor chip compared to the second region of the upper surface of the photonics integrated circuit chip, and
at least a portion of the first region of the upper surface of the photonics integrated circuit chip overlaps the semiconductor chip in a vertical direction.

4. The semiconductor package of claim 3, wherein
the photonics integrated circuit chip comprises a grid coupler configured to process optical signals,
the optical transmissive layer comprises a light incident region in an upper portion of the optical transmissive layer,
the grid coupler is on the second region of the upper surface of the photonics integrated circuit chip and is surrounded by the optical transmissive layer, and
the optical transmissive layer is configured to transfer optical signals to the grid coupler if the optical signals are input to the light incident region.

5. The semiconductor package of claim 4, wherein
the interposer comprises an upper redistribution structure,
the upper redistribution structure comprises a first insulation layer and a second insulation layer,
the first insulation layer and the second insulation layer are on the core substrate, upper surfaces of the plurality of photonics modules each include a light incident region and a remaining region,
the first insulation layer is on the remaining region of the upper surfaces of the plurality of photonics modules, and
the second insulation layer covers an upper surface of the first insulation layer.

6. The semiconductor package of claim 5, wherein
the first insulation layer comprises a first through hole extending to a lower surface of the first insulation layer from the upper surface of the first insulation layer,
the second insulation layer comprises a second through hole,
the second through hole has a same center axis as the first through hole,
the second through hole extends to a lower surface of the second insulation layer from an upper surface of the second insulation layer, and
the first through hole and the second through hole overlap the light incident region of the corresponding one of the plurality of photonics modules in a vertical direction.

7. The semiconductor package of claim 1, further comprising:
an optical fiber configured to provide optical signals to an upper surface of the optical transmissive layer in one of the plurality of photonics modules; and
a lid on the package substrate, the lid covering the semiconductor chip and the interposer,
wherein the optical fiber is coupled to the lid and faces the optical transmissive layer in the one of the plurality of photonics modules.

8. The semiconductor package of claim 1, wherein
the plurality of photonics modules each further comprise a first molding layer and a second molding layer,
in each of the plurality of photonics modules, the first molding layer surrounds a side surface of the photonics integrated circuit chip, and
in each of the plurality of photonics modules, the second molding layer surrounds an upper surface of the photonics integrated circuit chip, a side surface of the electronic integrated circuit chip, and a side surface of the optical transmissive layer.

9. The semiconductor package of claim 1, wherein
in each of the plurality of photonics modules, the optical transmissive layer comprises at least one material selected from the group consisting of silicon, quartz glass, indium phosphide (InP), gallium arsenic (GaAs), and ZBLAN glass.

10. A semiconductor package comprising:
an interposer;
a plurality of photonics modules in the interposer and configured to perform communication based on optical signals;
a first semiconductor chip on a center of an upper portion of the interposer; and
a second semiconductor chip laterally spaced apart from the first semiconductor chip, the second semiconductor chip on the upper portion of the interposer, wherein the interposer include a core substrate,
the core substrate includes a plurality of through electrodes and a plurality of cavities,
the plurality of through electrodes extend from an upper surface of the core substrate to a lower surface of the core substrate,
the plurality of cavities extend from the upper surface of the core substrate to an inner portion of the core substrate and the plurality of cavities are in a region of the interposer where the plurality of through electrodes are not disposed,
a corresponding one of the plurality of photonics modules is in each of the plurality of cavities, and
the plurality of photonics modules each include a photonics integrated circuit chip, an electronic integrated circuit chip on an upper surface of the photonics integrated circuit chip, and an optical transmissive layer on the upper surface of the photonics integrated circuit chip.

11. The semiconductor package of claim 10, wherein
the plurality of cavities in the interposer are arranged at regular intervals in a horizontal direction along a side surface of a center region of the core substrate,
each of the plurality of cavities comprises a first space disposed in the center region of the core substrate and a remaining space outside the center region of the core substrate, and
the center region of the core substrate is a region that overlaps the first semiconductor chip in a vertical direction.

12. The semiconductor package of claim 11, wherein
the remaining space comprises a second space outside an edge region of the core substrate and a third space in the edge region of the core substrate, and
the edge region of the core substrate is a region that overlaps the second semiconductor chip in the vertical direction.

13. The semiconductor package of claim 10, wherein,
in the plurality of photonics modules,
the electronic integrated circuit chip is on a first region of the upper surface of the photonics integrated circuit chip,
the optical transmissive layer is on a second region of the upper surface of the photonics integrated circuit chip,
the first region of the upper surface of the photonics integrated circuit chip is closer to the first semiconductor chip than the second region of the upper surface of the photonics integrated circuit chip,
in one of the plurality of cavities, the second region of the upper surface of the photonics integrated circuit chip is closer to the second semiconductor chip compared to the first region of the upper surface of the photonics integrated circuit chip, and
at least a portion of the first region of the upper surface of the photonics integrated circuit chip overlaps the first semiconductor chip in a vertical direction.

14. The semiconductor package of claim 13, wherein
in the plurality of photonics modules, at least a partial region of the second region of the upper surface of the photonics integrated circuit chip does not overlap the first semiconductor chip and the second semiconductor chip in the vertical direction.

15. The semiconductor package of claim 13, wherein, in the plurality of photonics modules,
the photonics integrated circuit chip comprises a grid coupler configured to process optical signals,
the optical transmissive layer comprises a light incident region in an upper portion of the optical transmissive layer,
the grid coupler is on the second region of the upper surface of the photonics integrated circuit chip and is surrounded by the optical transmissive layer, and
the optical transmissive layer is configured to transfer optical signals to the grid coupler if the optical signals are input to the light incident region.

16. The semiconductor package of claim 10, wherein
the interposer comprises an upper redistribution structure,
the upper redistribution structure comprises a first insulation layer and a second insulation layer,
the first insulation layer and the second insulation layer are on the core substrate,
upper surfaces of the plurality of photonics modules each include a light incident region and a remaining region,
the first insulation layer is on the remaining region of the upper surfaces of the plurality of photonics modules, and
the second insulation layer covers an upper surface of the first insulation layer.

17. The semiconductor package of claim 16, wherein
the first insulation layer comprises a first through hole extending to a lower surface of the first insulation layer from the upper surface of the first insulation layer,
the second insulation layer comprises a second through hole,
the second through hole has a same center axis as the first through hole,
the second through hole extends to a lower surface of the second insulation layer from an upper surface of the second insulation layer, and
the first through hole and the second through hole overlap the light incident region in a vertical direction.

18. The semiconductor package of claim 10, further comprising:
an optical fiber configured to provide optical signals to an upper surface of the optical transmissive layer in one of the plurality of photonics modules; and
a lid covering the first semiconductor chip, the second semiconductor chip, and the interposer,
wherein the optical fiber is coupled to the lid and faces the optical transmissive layer in the one of the plurality of photonics modules.

19. A semiconductor package comprising:
a package substrate;
an interposer on the package substrate;
a plurality of photonics modules in the interposer and configured to perform communication based on optical signals;
a first semiconductor chip on a center of an upper portion of the interposer;
a second semiconductor chip laterally spaced apart from the first semiconductor chip and on the upper portion of the interposer; and
a lid on the package substrate, the lid covering the interposer, the first semiconductor chip, and the second semiconductor chip, wherein
the lid includes an optical fiber facing the interposer,
the interposer includes a core substrate,
the core substrate includes a plurality of through electrodes and a plurality of cavities,
the plurality of through electrodes extend from an upper surface of the core substrate to a lower surface of the core substrate,
the plurality of cavities extend from the upper surface of the core substrate to an inner portion of the core substrate and the plurality of cavities are in a region of the interposer where the plurality of through electrodes are not disposed,
a corresponding one of the plurality of photonics modules is in each of the plurality of cavities, and
the plurality of photonics modules each include a photonics integrated circuit chip, an electronic integrated circuit chip on a first region of an upper surface of the photonics integrated circuit chip, and an optical transmissive layer on a second region of the upper surface of the photonics integrated circuit chip,
in one of the plurality of photonics modules in one of the plurality of cavities, the first region of the upper surface of the photonics integrated circuit chip is closer to the first semiconductor chip compared to the second region of the upper surface of the photonics integrated circuit chip, the second region of the upper surface of the photonics integrated circuit chip is closer to the second semiconductor chip compared to the first region of the photonics integrated circuit chip, and at least a portion of the first region of the photonics integrated circuit chip overlaps the first semiconductor chip in a vertical direction.

20. The semiconductor package of claim 19, wherein
the plurality of cavities in the interposer are arranged at regular intervals in a horizontal direction along a side surface of a center region of the core substrate,
each of the plurality of cavities comprises a first space in the center region of the core substrate and a second space outside the center region of the core substrate, and
the center region of the core substrate is a region that overlaps the first semiconductor chip in the vertical direction.
